(19) United States
(12) Patent Application Publication
(10) Pub. No.: US 2010/0126583 A1
(43) Pub. Date: May 27, 2010

(54) THIN FILM SOLAR CELL AND METHOD OF MANUFACTURING THE SAME

(76) Inventors: JEONGWOO LEE, PAJU-SI (KR); WONSEO PARK, GOYANG-SI (KR); SEONGKEE PARK, GOYANG-SI (KR); TAEYOUN KIM, SEOUL (KR)

Correspondence Address: BIRCH STEWART KOLASCH & BIRCH, PO BOX 747, FALLS CHURCH, VA, 22040-0747, US

(21) Appl. No.: 12/624,029

(22) Filed: Nov. 23, 2009

(30) Foreign Application Priority Data
Nov. 25, 2008 (KR) 10-2008-0117588
Nov. 13, 2009 (KR) 10-2009-0109860

(51) Int. Cl. H01L 31/00; H01L 31/18

(52) U.S. Cl. 136/256; 438/72; 438/73; 257/E31.127; 257/E31.119

(57) ABSTRACT

A thin film solar cell and a method of manufacturing the same are provided. The thin film solar cell includes a substrate; a transparent layer positioned on the substrate and comprising a plurality of microlenses; a first electrode positioned on the transparent layer; an absorption layer to generate electron-hole pairs from incident light, and positioned on the first electrode; and a second electrode positioned on the absorption layer.

This application claims the benefit of Korean Patent Application No. 10-2008-0117588 filed on Nov. 25, 2008 and No. 10-2009-0109860 filed on Nov. 13, 2009, the disclosure of which is hereby incorporated by reference in its entirety.

### BACKGROUND OF THE INVENTION

1. Field of the Invention

Embodiments of the invention relate to a thin film solar cell and a method of manufacturing the same.

2. Discussion of the Related Art

Nowadays, in order to solve the energy problem many are facing, various researches for a fuel that can replace existing fossil fuels have been advanced. Particularly, various researches for using natural and renewable energy such as a wind force, atomic energy, and solar energy to replace petroleum resources, for example, to be exhausted within several decades have been advanced.

Because a solar cell uses solar energy, which is a virtually infinite and, environmental-friendly energy source, unlike other energy sources, much research has been performed for the last several decades since a Se solar cell was developed in 1983. A currently commercialized solar cell using a monocrystal bulk silicon is not more widely used due to high production and installation costs.

In order to solve such a cost problem, research for a thin film solar cell is actively performed, and a large area solar cell can be manufactured at low cost via a technique for manufacturing a thin film solar cell using amorphous silicon (a-Si:H), and thus, interest has increased in the thin film solar cell using the amorphous silicon (a-Si:H).

In general, a thin film solar cell has a form in which a first electrode, an absorption layer, and a second electrode are stacked on a first substrate, and in order to improve the efficiency, an unevenness is formed on a surface of the first electrode. Conventionally, as a method of forming the unevenness on the surface of the first electrode, a chemical etching method using an acid/base solution has been used.

However, in order to use the chemical etching method, an etching solution should be changed according to a material of the first electrode that is used, and it is difficult to freely adjust the form of the unevenness. Further, there is a problem of waste processing of a waste acid/base etching solution after use, and thus, which requires an urgent solution.

### SUMMARY OF THE INVENTION

Embodiments of the invention are directed to a thin film solar cell and a method of manufacturing the same that can easily form an unevenness, be environmental-friendly, and reduce or prevent an electrical characteristic of a solar cell from being deteriorated.

According to an embodiment of the invention, provided is a thin film solar cell including a substrate; a transparent layer positioned on the substrate and comprising a plurality of microlenses; a first electrode positioned on the transparent layer; an absorption layer to generate electron-hole pairs from incident light, and positioned on the first electrode; and a second electrode positioned on the absorption layer.

According to an embodiment of the invention, provided is a method of manufacturing a thin film solar cell including coating a resin on a substrate; forming a transparent layer comprising a plurality of microlenses from the coated resin by using a mold; forming a first electrode on the transparent layer; forming an absorption layer which generates electron-hole pairs from incident light on the first electrode; and forming a second electrode on the absorption layer.

According to an embodiment of the invention, provided is a thin film solar cell including a substrate; a transparent layer positioned on the substrate and comprising a plurality of periodic protrusions; a first electrode positioned on the transparent layer; an absorption layer to generate electron-hole pairs from incident light, and positioned on the first electrode; and a second electrode positioned on the absorption layer.

Other embodiments will be disclosed in the detailed description.

### BRIEF DESCRIPTION OF THE DRAWINGS

The accompany drawings, which provide a further understanding of the invention, which are incorporated and constitute a part of this specification, illustrate embodiments of the invention, and together with the description, serve to explain the principles of the invention.

FIG. 1 is a cross-sectional view illustrating a thin film solar cell according to an embodiment of the invention;

FIGS. 2a-2e are perspective views illustrating various forms of an uneven layer of a thin film solar cell according to an embodiment of the invention;

FIG. 3 is a view of a microlens according to an embodiment of the invention;

FIG. 4 is a diagram illustrating focusing and scattering of light of a thin film solar cell according to an embodiment of the invention; and

FIGS. 5a to 5g are perspective views illustrating processes of a method of manufacturing a thin film solar cell according to an embodiment of the invention.

### DETAILED DESCRIPTION OF THE EMBODIMENTS

Reference will now be made in detail embodiments of the invention, examples of which are illustrated in the accompanying drawings.

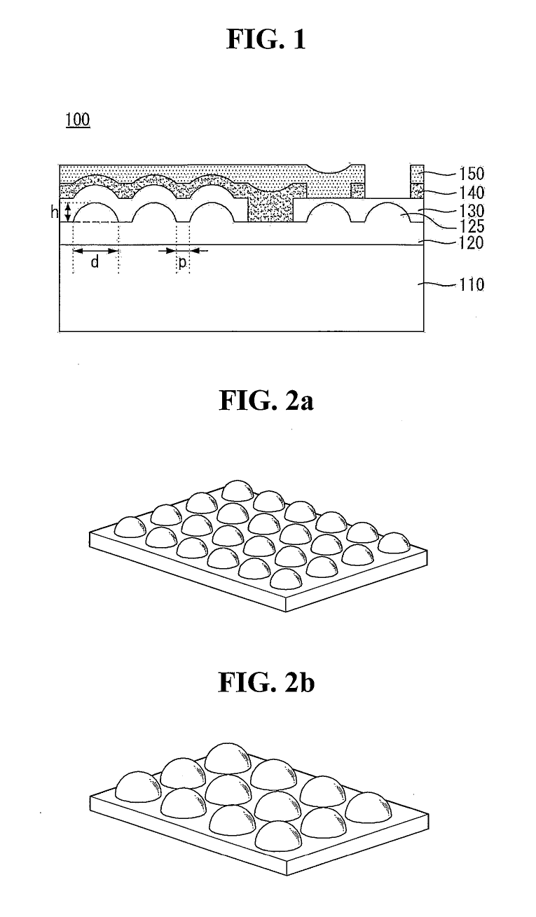

FIG. 1 is a cross-sectional view illustrating a thin film solar cell according to an embodiment of the invention. Referring to FIG. 1, a thin film solar cell 100 according to an embodiment comprises a substrate 110, an uneven layer 120 positioned on the substrate 110 and comprising a plurality of protrusions 125, a first electrode 130 positioned on the uneven layer 120, an absorption layer 140 positioned on the first electrode 130, and a second electrode 150 positioned on the absorption layer 140.

The substrate 110 is made of glass or a transparent resin film. The glass uses a flat plate glass having silicon oxide (SiO₂), sodium oxide (Na₂O), and/or calcium oxide (CaO) having high transparency and insulating property as a main component.

The uneven layer 120 increases a light trapping effect by reducing or preventing total reflection of incident light and by enlarging light scattering, and thus performs a function of increasing the efficiency of the thin film solar cell 100.

Because the uneven layer 120 should transmit light, the uneven layer 120 is made of a light transparent resin. Here, the light transparent resin is made of an acryl-based monomer and may be formed with one selected from a group consisting of polyethylene terephthalate (PET), polycarbonate (PC), polypropylene (PP), polyethylene (PE), polystyrene (PS), and poly epoxy, but a material of the light transparent resin is not limited thereto.

The uneven layer 120 comprises the plurality of protrusions 125. The plurality of protrusions 125 may be periodically placed on the uneven layer 120, or may be formed together with the uneven layer 120 in a unitary fashion. The plurality of protrusions 125 may have various shapes, for example, a saw-toothed shape, a convex shape, a columnar shape, a pyramidal shape, a ridge shape, or other shapes. In one embodiment of the invention, the plurality of protrusions is microlenses 125. The microlens 125 may have a protruded form of an embossed hemispherical shape.

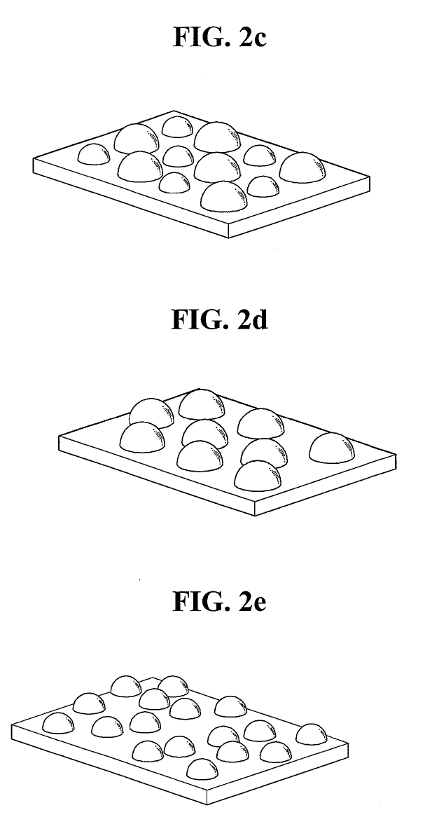

FIG. 2 is a perspective view illustrating various forms of an uneven layer of a thin film solar cell according to an embodiment of the invention. Referring to FIGS. 1, and 2a to 2e, the microlens 125 can have different diffusion, refraction, and focusing characteristics of light according to a size and density thereof. Accordingly, as shown in FIGS. 2a to 2c, a lens diameter d of the microlens 125 may be uniform or non-uniform, and a height h of the microlens 125 may also be uniform or non-uniform.

That is, as is shown in FIGS. 2a and 2b, the diameters d and the heights h of a plurality of the microlenses 125 may all be uniform on the uneven layer 120. Additionally, as shown in FIG. 2c, the diameters d and/or the heights h of the plurality of microlenses 125 may be non-uniform. The plurality of non-uniform microlenses may be arranged in periodic order, as shown in FIG. 2c, where rows of larger microlenses alternate with rows of smaller microlenses, but the plurality of non-uniform microlenses can also be randomly positioned. The microlens 125 can be regularly arranged and arrangement between central points of the microlens 125 can be formed in a line.

However, as shown in FIG. 2(d). in arrangement of the microlens 125, central points of the microlens 125 can be disposed in an oblique line. Further, as shown in FIG. 2(e), the microlens 125 can be irregularly arranged and central points of the microlens 125 may be randomly arranged

Further, the diameter d of the microlens 125 is about 1 to about 10 μm, but is not limited thereto. The height h of the microlens 125 is about ½ or less of a diameter d of the microlens 125. Further, a gap p between the microlenses 125 is about ¼ or less of the diameter d of the microlens 125, but is not limited thereto.

An occupying area of the microlens 125 is about 50 to about 90% or more of, for example, an entire area of the uneven layer 120, but is not limited thereto.

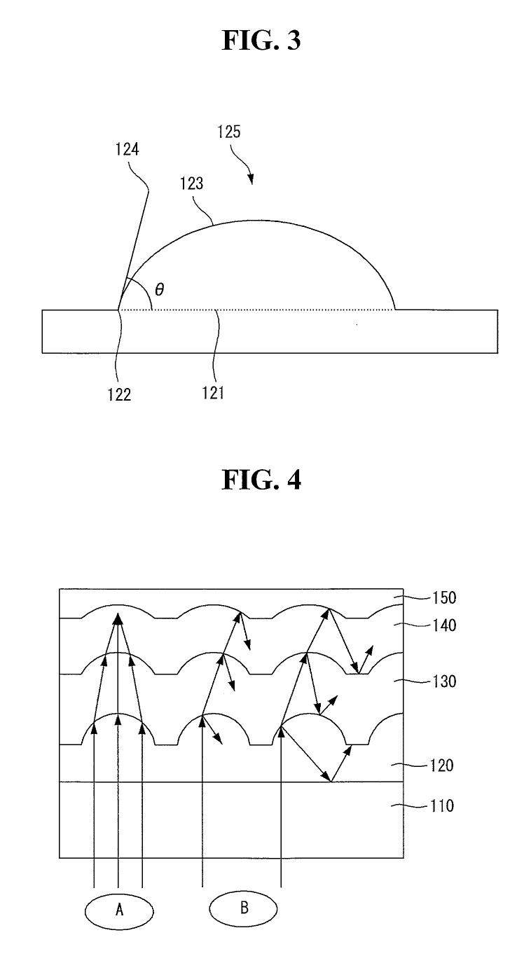

FIG. 3 is a view of a microlens according to an embodiment of the invention. The microlens 125 has a planar base 121, and a curved surface 123 over the base 121 that contacts the base 121 at least one point 122. A tangent line 124 may be defined at the at least one point 122 where the curved surface 123 contacts the base 121. In this case, an contact angle θ is defined between the base 121 and the tangent line 124 of the curved surface 123 at the at least one point 122. In embodiments of the invention, the contact angle θ may be about 30° to 90°. One or more of microlenses 125 may have the contact angle θ of about 45° to 60°.

As described above, when the microlens 125 is formed in an embossed hemispherical shape, some of light applied from the outside, for example, a lower part of the microlens 125, is uniformly refracted in entire or all the orientation angles of the hemispherical shape to be transmitted in the microlens 125. Thereby, some of light applied from a lower part of the microlens 125 is uniformly diffused upward.

The first electrode 130 is made of a transparent conductive oxide or a metal. The transparent conductive oxide used may be an indium tin oxide (ITO), a tin oxide (SnO₂), a zinc oxide (ZnO), or others. In embodiments of the invention, the transparent conductive oxide is ITO. The metal used may be silver (Ag), aluminum (Al), or others.

The first electrode 130 is formed with a single layer made of a transparent conductive oxide or a metal, but is not limited thereto and may be formed with a multiple layer in which two layers or more of a transparent conductive oxide/metal are stacked.

The absorption layer 140 is made of amorphous silicon and can have a pin structure. Here, the referred pin structure may be a stacked structure of a p+ type amorphous silicon layer/intrinsic-type amorphous silicon layer/n+ amorphous silicon layer.

Here, in the pin structure, when light, such as sun light, is applied, a silicon thin film layer absorbs the light and thus an electron-hole pair is generated. In the pin structure, by a built-in potential generated with a p-type and an n-type, the generated electrons and holes are moved to n-type and p-type semiconductors, respectively, and are used generate a current, for example.

In the embodiments of the invention, the absorption layer 140 is shown as only one layer, however the absorption layer 140 has a stacked structure formed with a p+ type amorphous silicon layer/intrinsic-type amorphous silicon layer/n+ amorphous silicon layer to generate electron-hole pairs, and to move the generated electrons and holes.

Like the first electrode 130, the second electrode 150 is made of a transparent conductive oxide or a metal. The transparent conductive oxide used may be indium tin oxide (ITO), tin oxide (SnO₂), zinc oxide (ZnO), or others. In embodiments of the invention, the transparent conductive oxide is ITO. The metal used may be silver (Ag), aluminum (Al), or others.

The second electrode 150 is formed with a single layer made of a transparent conductive oxide or a metal, but is not limited thereto, and can be stacked with two layers or more of a transparent conductive oxide/metal.

FIG. 4 is a diagram illustrating focusing and scattering of light of a thin film solar cell according to an embodiment of the invention.

Referring to FIG. 4, light applied through the substrate 110 can be simultaneously focused and scattered within a thin film solar cell.

In more detail, focused light A among light applied through the substrate 110 is focused through a microlens of the uneven layer 120 and can be focused even in an interface of the first electrode 130. Therefore, due to a focusing effect of a microlens of the uneven layer 120, a focal depth of applied light is sustained and thus an effective light transmission effect can be obtained. Further, scattered light B among light applied through the substrate 110 can be scattered while being focused in an interface of a microlens of the uneven layer 120. Light transmitted the uneven layer 120 is again scattered while being focused in an interface of the first electrode 130 and light transmitted the first electrode 130 can be scattered while being focused again in an interface of the absorption layer 140. Therefore, due to scattering of applied light by a microlens of the uneven layer 120, a light path transferred to the absorption layer 140 largely increases, thereby improving electrical efficiency of a thin film solar cell.

Hereinafter, a method of manufacturing a thin film solar cell according to an embodiment of the invention will be described.

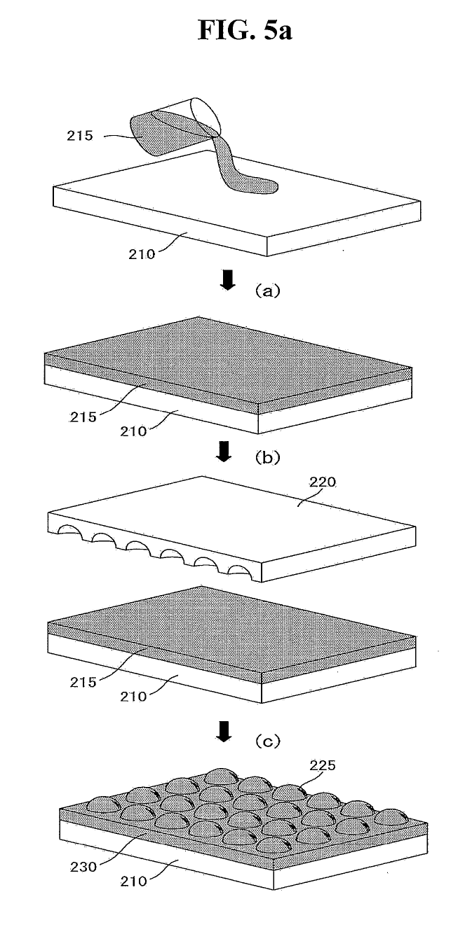

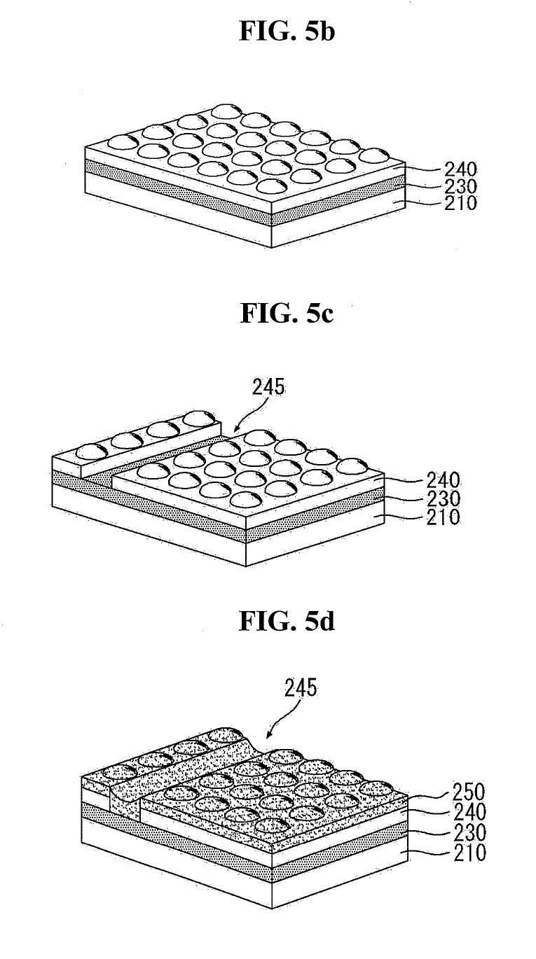

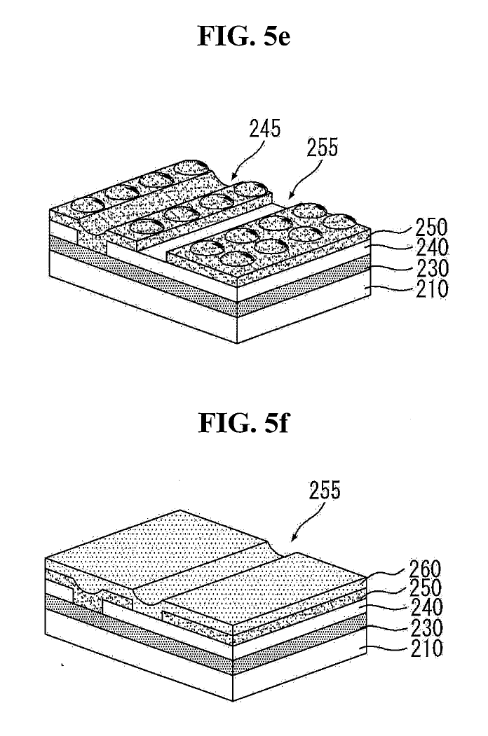

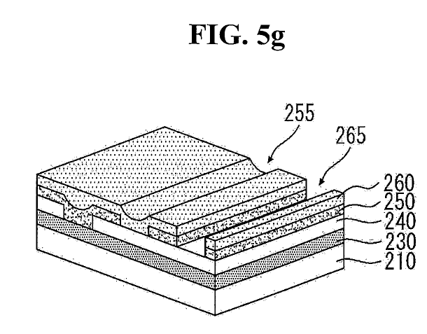

FIGS. 5a to 5g are perspective views illustrating processes of a method of manufacturing a thin film solar cell according to an embodiment of the invention.

Referring to FIG. 5a, (a) a resin 215 is coated on a substrate 210. In this case, the substrate 210 is made of glass or a transparent resin film. The glass can use a flat plate glass having silicon oxide (SiO₂), sodium oxide (Na₂O), and/or calcium oxide (CaO) having high transparency and insulating property as a main component.

The resin 215 is formed with an acryl-based monomer, but may be formed with one selected from a group consisting of polyethylene terephthalate (PET), polycarbonate (PC), polypropylene (PP), polyethylene (PE), polystyrene (PS), and poly epoxy.

Next, (b) a mold 220 is prepared or positioned on the substrate 210 in which the resin 215 is coated. In the mold 220, an inverse image of a microlens 225 is engraved. Because the inverse image of the microlens 225 engraved in the mold 220 determines a form of the microlens 225 to be formed in the resin 215, a diameter d and a height h of the microlens 225, and a gap p between the microlens 225 should be accurately designed.

Next, (c) an uneven layer 230 comprising a plurality of microlenses 225 is formed by being stamped with the mold 220 on the substrate 210 in which the resin 215 is coated. While the resin 215 is being stamped by the mold 220, ultraviolet (UV) light may be applied to the coated resin to set the microlenses 225. Then, once the mold 220 is removed, the set resin may be subjected to heat to further harden the microlenses 225. Here, heat curing is performed for 30 minutes at a temperature of about 230° C.

In this time, a lens diameter d of the microlens 225 is uniform or non-uniform, and a height h of the microlens 225 is also uniform or non-uniform.

Further, the diameter d of the microlens 225 is about 1 to about 10 μm, but is not limited thereto. The height h of the microlens 225 is about ½ or less of the diameter d of the microlens 225. Further, a gap p between the microlenses 225 may be about ¼ or less of the diameter d of the microlens 225, but is not limited thereto. An occupying area of the microlens 225 may be 50 to 90% or more than, for example, of an entire area of the uneven layer 120, but is not limited thereto.

Referring to FIG. 5b, a first electrode 240 is formed on the substrate 210 in which the uneven layer 230 is formed. The first electrode 240 is made of a transparent conductive oxide or a metal. The transparent conductive oxide used may be an indium tin oxide (ITO), a tin oxide (SnO₂), a zinc oxide (ZnO), or other. In embodiments of the invention, the transparent conductive oxide is ITO. The metal used may be silver (Ag) aluminum (Al), or others.

Further, the first electrode 240 is formed with a single layer made of a transparent conductive oxide or a metal, but is not limited thereto and may be formed with a multiple layer in which two layers or more of a transparent conductive oxide/metal are stacked.

The first electrode 240 can be formed with chemical vapor deposition (CVD), physical vapor deposition (PVD), an electron beam (E-beam) method, or others. In this case, when the first electrode 240 is deposited on the substrate 210 in which the uneven layer 230 is formed, the first electrode 240 is formed along a step coverage of a microlens shape of the uneven layer 230, and thus, a microlens shape is displayed on a surface of the first electrode 240.

Therefore, a conventional process of forming an uneven portion in the first electrode using an acid/base etching solution may be omitted. Accordingly, unevenness can be easily formed on the first electrode, and the process is environment-friendly and reduces prevents an electrical characteristic of a solar cell from being deteriorated.

Next, referring to FIG. 5c, the first electrode 240 is patterned. In this case, as a method of patterning the first electrode 240, a photoresist method, a sand blast method, and/or a laser scribing method are used. Here, the first electrode 240 can be separated by a first patterned line 245.

Next, referring to FIG. 5d, an absorption layer 250 is formed on the first electrode 240 in which the patterning process is terminated. In this case, the absorption layer 250 is made of amorphous silicon and is stacked as a pin structure. Here, the pin structure may be a stacked structure of a p+ type amorphous silicon layer/intrinsic-type amorphous silicon layer/n+ amorphous silicon layer.

In the pin structure, when light, such as sun light, is applied, a silicon thin film layer absorbs the light, and thus, an electron-hole pair is generated. In the pin structure, by a built-in potential generated with a p-type and an n-type, the generated electron and hole are moved to n-type and p-type semiconductors, respectively, and are used.

In embodiments of the present invention, the absorption layer 250 is shown as only one layer, but the absorption layer 250 can have a structure stacked with a p+ type amorphous silicon layer/intrinsic-type amorphous silicon layer/n+ amorphous silicon layer.

In this case, the absorption layer 250 can be formed by sequentially depositing amorphous silicon layers with a plasma enhanced chemical vapor deposition (PECVD) method.

Next, referring to FIG. 5e, the absorption layer 250 is patterned. In this case, the absorption layer 250, having an area separated from a first patterning line 245 in which the first electrode 240 is patterned, is patterned. Here, as a method of patterning the absorption layer 250, a photoresist method, a sand blast method, and/or a laser scribing method are used. Therefore, the absorption layer 250 can be separated by a second patterning line 255.

Next, referring to FIG. 5f, a second electrode 260 is formed on the substrate 210 in which a patterning process of the absorption layer 250 is terminated. Like the first electrode 240, the second electrode 260 is made of a transparent conductive oxide or a metal. The transparent conductive oxide used may be an indium tin oxide (ITO), a tin oxide (SnO₂), a zinc oxide (ZnO), or others. In embodiments of the invention, the transparent conductive oxide is ITO. The metal used may be silver (Ag), aluminum (Al), or others.

The second electrode 260 is formed with a single layer made of a transparent conductive oxide or a metal, but is not limited thereto and may be stacked with two layers or more of a transparent conductive oxide/metal.

In this case, like the first electrode 240, the second electrode 260 can be formed with chemical vapor deposition (CVD), physical vapor deposition (PVD), and/or an electron beam (E-beam) method.

Finally, referring to FIG. 5g, for electrical insulation, the absorption layer 250 and the second electrode 260 formed on the substrate 210 are patterned.

In this case, by patterning an area separated from the first patterning line 245 and the second patterning line 255, the area can be electrically insulated by a third patterning line 265.

Therefore, as described above, a thin film solar cell in the present implementation can be manufactured.

As described above, in a thin film solar cell and a method of manufacturing the same of this document, by forming an uneven layer using a resin on the first substrate, an uneven structure can be easily formed in the solar cell.

Further, because a conventional acid/base etching solution is not used, the method is environment-friendly, and because a surface of the first electrode is not etched, an electrical characteristic of the solar cell can be reduced or prevented from being deteriorated.

The foregoing embodiments and advantages are merely examples and are not to be construed as limiting the invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures. Moreover, unless the term “means” is explicitly recited in a limitation of the claims, such limitation is not intended to be interpreted under 35 USC 112 (6).

What is claimed is:

1. A thin film solar cell, comprising:
a substrate;
a transparent layer positioned on the substrate and comprising a plurality of microlenses;
a first electrode positioned on the transparent layer;
an absorption layer to generate electron-hole pairs from incident light, and positioned on the first electrode; and
a second electrode positioned on the absorption layer.

2. The thin film solar cell of claim 1, wherein the transparent layer is made of an acryl-based monomer.

3. The thin film solar cell of claim 1, wherein the plurality of microlenses have diameters of about 1 to about 10 μm.

4. The thin film solar cell of claim 1, wherein diameters of the plurality of microlenses are uniform.

5. The thin film solar cell of claim 1, wherein diameters of the plurality of microlenses are non-uniform.

6. The thin film solar cell of claim 1, wherein a height of the plurality of microlenses is about ½ or less of a diameter of at least one of the plurality of microlenses.

7. The thin film solar cell of claim 1, wherein a gap between the plurality of microlenses is about ¼ or less of a diameter of at least one of the plurality of microlenses.

8. The thin film solar cell of claim 1, wherein heights of the plurality of microlenses are uniform.

9. The thin film solar cell of claim 1, wherein heights of the plurality of microlenses are non-uniform.

10. The thin film solar cell of claim 1, wherein a shape of the plurality of microlenses is a protruding embossed hemisphere.

11. The thin film solar cell of claim 1, wherein the protruding embossed hemisphere shape of the plurality of microlenses is imparted on the first electrode layer so that portions of the first electrode layer have the protruding embossed hemisphere shape.

12. The thin film solar cell of claim 1, wherein at least one of the plurality of microlenses has a planar base, a curved surface over the base that contacts the base at least one point, and an angle defined between the base and a tangent line of the curved surface at the at least one point that is about 45° to about 60°.

13. A method of manufacturing a thin film solar cell, comprising:
coating a resin on a substrate;
forming a transparent layer comprising a plurality of microlenses from the coated resin by using a mold;
forming a first electrode on the transparent layer;
forming an absorption layer which generates electron-hole pairs from incident light on the first electrode; and
forming a second electrode on the absorption layer.

14. The method of claim 13, wherein forming of the transparent layer comprises:
applying ultraviolet cm light to the coated resin while being stamped by the mold to set the coated resin; and
heating the set resin to harden the set resin.

15. The method of claim 13, wherein a height of the plurality of microlenses is about ½ or less of a diameter of the at least one of the plurality of microlenses.

16. The method of claim 13, wherein a gap between the plurality of microlenses is about ¼ or less of a diameter of the at least one of the plurality of microlenses.

17. The method of claim 13, wherein the plurality of microlenses is formed in a shape of a protruding embossed hemisphere.

18. The method of claim 13, wherein the first electrode is formed so that the embossed hemisphere shape of the plurality of microlenses is imparted on the first electrode layer and portions of the first electrode layer have the protruding embossed hemisphere shape.

19. The method of claim 13, wherein at least one of the plurality of microlenses is formed to have a planar base, a curved surface over the base that contacts the base at least one point, and an angle defined between the base and a tangent line of the curved surface at the at least one point that is about 45° to about 60°.

20. A thin film solar cell, comprising:
a substrate;
a transparent layer positioned on the substrate and comprising a plurality of periodic protrusions;
a first electrode positioned on the transparent layer;
an absorption layer to generate electron-hole pairs from incident light, and positioned on the first electrode; and
a second electrode positioned on the absorption layer.

21. The thin film solar cell of claim 20, wherein the plurality of periodic protrusions has an embossed hemisphere shape.

22. The thin film solar cell of claim 20, wherein a height of the plurality of periodic protrusions is about ½ or less of a base of the at least one of the plurality of periodic protrusions.

23. The thin film solar cell of claim 20, wherein a gap between the plurality of periodic protrusions is about ¼ or less of a diameter of the at least one of the plurality of periodic protrusions.
